(19) United States
(12) Patent Application Publication
(10) Pub. No.: US 2008/0116518 A1
(43) Pub. Date: May 22, 2008

(54) METAL-OXIDE-SEMICONDUCTOR DEVICE AND MANUFACTURING METHOD THEREOF

(75) Inventors: Tung-Cheng Kuo, Hsinchu City (TW); Yi-Lin Chen, Taipei City (TW)

Correspondence Address: ROSENBERG, KLEIN & LEE, 3458 ELLICOTT CENTER DRIVE-SUITE 101, ELLICOTT CITY, MD, 21043, US

(73) Assignee: Realtek Semiconductor Corp., Hsinchu (TW)

(21) Appl. No.: 11/940,677

(22) Filed: Nov. 15, 2007

(30) Foreign Application Priority Data
Nov. 17, 2006 (TW) 095142667

(51) Int. Cl. H01L 23/62; H01L 21/8238

(52) U.S. Cl. 257/357; 438/217; 257/E27.064; 257/E21.632

(57) ABSTRACT

The present invention provides a device for ESD protection and voltage stabilizing in order to let chip space be put in better utilization. During different conditions (i.e. ESD current occurrences and normal operation), identical elements of the device are used both for ESD protection and for voltage stabilization. The chip size and manufacturing costs necessary for the additional voltage stabilizing capacitors are thereby saved.

### FIELD OF THE INVENTION

The present invention is generally related to a metal-oxide-semiconductor (MOS) device and particularly to a MOS device with voltage stabilizing capability and electrostatic-discharge protection and the manufacturing method thereof.

### BACKGROUND OF THE INVENTION

With the continuous advancement of semiconductor technology, the size of a complementary metal-oxide-semiconductor (CMOS) device enters the deep submicron region from the original submicron region. Accordingly, the trend is to reduce the size of chips without a loss of function and probably even a boost in performance. In general, to prevent damage caused by electrostatic discharge (ESD) in an input/output (I/O) pad, several dummy n-type and p-type metal-oxide-semiconductor field-effect transistors (NMOSFETs, PMOSFETs) are implemented for increasing the total channel width of the NMOSFETs and the PMOSFETs to act as ESD protection devices. However, when a chip is in operation, the dummy MOSFETs are turned off (i.e. the gates of NMOSFETs are connected to the ground, while the gates of PMOSFETs are connected to the power supply).

FIG. 1 shows a structural cross-sectional view of a conventional NMOSFET with ESD protection. Referring to the figure, the NMOSFET contains a p-type substrate 1′, a p-type doping region 14′ for grounding, a first n-type doping region 10′ as a drain connected to an I/O pad 4′, and a second n-type doping region 12′ as a source connected to ground. A gate oxide 2′ resides above the region between the first n-type doping region 10′ and the second n-type doping region 12′ and is used as an insulation layer. A polysilicon layer 3′ is set on top of the gate oxide 2′, and is used as a gate electrode. During normal operation, the NMOSFET is turned off (i.e. the gate is grounded). When static charges occur, they are discharged through the PN junction formed by the second n-type doping region 12′ and the p-type substrate 1′, or directed to ground through the second n-type doping region 12′, the p-type substrate 1′, and the first n-type doping region 10 by the bipolar-transistor effect. In addition, the NMOSFET of a power supply pad (V_{DD} Pad) is also turned off during normal operations.

Although the effectiveness of ESD protection in the structure of conventional semiconductor devices is acceptable, the idle NMOSFETs are redundant during normal operation. Accordingly, a novel semiconductor device structure should make use of the redundant elements during normal operation in order to reduce chip size and cost.

### SUMMARY

The objective of the present invention is to provide ESD protection and voltage stabilizing between a power supply and ground for better utilization of chip space.

Another objective of the present invention is to reduce the chip size and consequently the cost by using a dummy MOSFET between the power supply and the ground as a voltage-stabilizing capacitor.

In order to achieve the objectives described above, the present invention uses a dummy MOSFET in a chip for ESD protection when the chip is not installed or not in operation and as a voltage-stabilizing capacitor when the chip is in operation. Since the MOSFET is used as a voltage-stabilizing capacitor, extra capacitors are no longer necessary. Therefore, the chip size and cost are reduced.

### BRIEF DESCRIPTION OF THE DRAWINGS

FIG. 1 shows a structural cross-sectional view of an NMOSFET with ESD protection according to the prior art.

FIG. 2A shows a structural cross-sectional view of a MOSFET with voltage-stabilizing capability and ESD protection according to a preferred embodiment of the present invention.

FIG. 2B shows a structural cross-sectional view of a MOSFET with the fourth n-type doping region formed by punch-through of the second n-type doping region and the third n-type doping region according to a preferred embodiment of the present invention.

FIG. 3 shows a flowchart for manufacturing a MOSFET with voltage-stabilizing capability and ESD protection according to a preferred embodiment of the present invention.

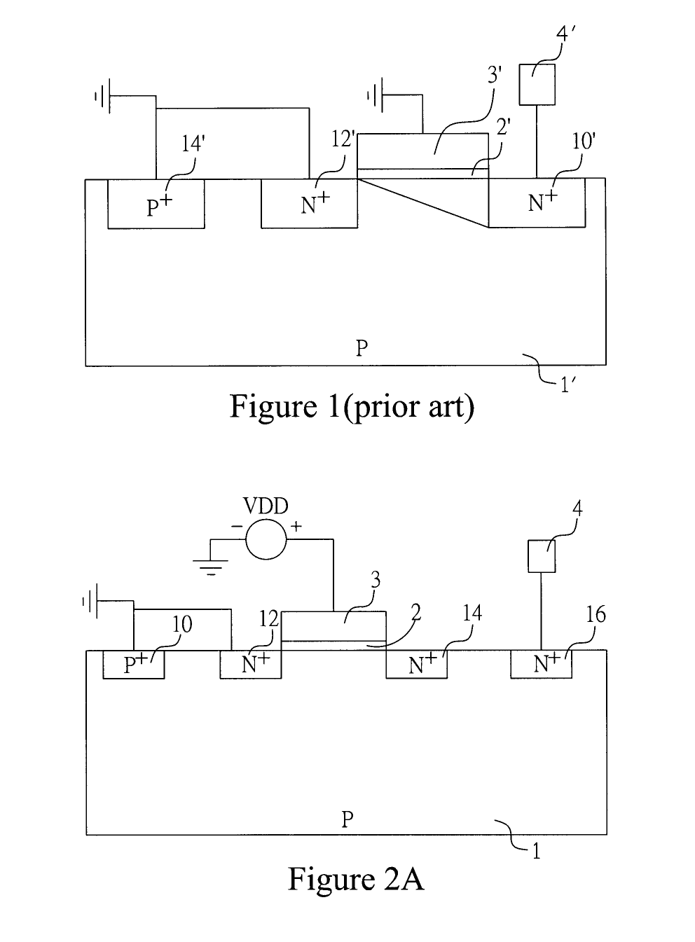

### DETAILED DESCRIPTION

In order to gain a further understanding of the structure and characteristics as well as the effectiveness of the present invention, the detailed description of this invention is provided as follows along with preferred embodiments and accompanying figures.

The present invention provides a MOSFET with the capability of voltage stabilizing besides the conventional ESD protection. Such that the MOSFET is used as an ESD protector and additionally, a voltage-stabilizing capacitor between the power supply and ground.

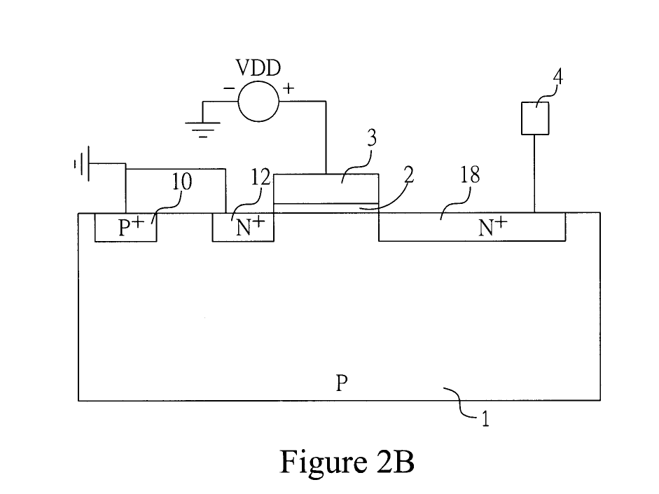

FIGS. 2A and 2B illustrate the structural cross-sectional views of the MOSFET of a preferred embodiment in the present invention. As shown in the figures, the MOSFET contains a p-type substrate 1, a first n-type doping region 12, a second n-type doping region 14, a third n-type doping region 16, a p-type doping region 10, a gate oxide layer 2, a conducting layer 3, and a pad 4. An NMOSFET is used as the voltage-stabilizing capacitor, which is fabricated on a chip. The gate oxide layer 2 is formed on the p-type substrate 1. The conducting layer is then formed above the gate oxide layer 2. The first n-type doping region 12, the second n-type doping region 14, and the third n-type doping region 16 are formed on the p-type substrate 1 by ion implantation, where the first and the second n-type doping region 12, 14 are located on either side of the gate oxide layer 2. The p-type doping region 10 is for grounding the p-type substrate 1.

The first n-type doping region 12 is used as a source electrode and is connected to ground. The conducting layer 3 is used as a gate electrode and is connected to the power supply. The third n-type doping region 16 is used as a drain electrode, and is connected to the pad 4, which can be a power supply pad (V_{DD} Pad), or an input/output (I/O) pad. When the current generated by static charges is directed through the chip to the pad 4, it is guided to the third n-type doping region 16. At this time, because the energy of the static charges is greater than the potential barrier between the third n-type doping region 16 and the second n-type doping region 14, the current will pass through the p-type substrate 1 between the third n-type doping region 16 and the second n-type doping region 14. As a result, the third n-type doping region 16 and the second n-type doping region 14 can be regarded as a single n-type doping region, which is a fourth n-type doping region 18 (as shown in FIG. 2B).

Next, the current passes through the PN junction formed by the fourth n-type doping region 18 and the p-type substrate 1, and is subsequently directed to the ground via the p-type doping region 10. The bipolar-transistor effect produced by the fourth n-type doping region 18, p-type substrate 1, and first n-type doping region 12 will direct the current to ground, thereby achieving ESD protection. In addition, when the third n-type doping region 16 is connected to the V_{DD} pad, the current can be directed to the first n-type doping region 12 via the fourth n-type doping region 18 and finally to the ground, since the fourth n-type doping region 18 and the conducting layer 3 are connected to the power supply. Accordingly, ESD protection is also achieved.

During normal operation, the NMOSFET for ESD protection is no longer necessary. In this case, the NMOSFET forms a gate capacitor with the conducting layer 3, the p-type substrate 1, the first n-type doping region 12, and the second n-type doping region 14. The conducting layer 3 is connected to the power supply, the first n-type doping region 12 is connected to ground, and the second n-type doping region 14 is held at zero potential. Therefore, the NMOSFET can be used as a voltage-stabilizing capacitor kept between the power supply and ground.

In order to fabricate the MOSFET described above to be an exceptional voltage-stabilizing capacitor, the potential barrier between the second n-type doping region 14 and the third n-type doping region 16 must be sufficiently high. The potential barrier can be adjusted by adopting p-type ESD implantation (PESD) between the second n-type doping region 14 and the third n-type doping region 16, or by doping n-type ions with different concentrations between the second n-type doping region 14 and the third n-type doping region 16 for a change of concentration or size of the region in between.

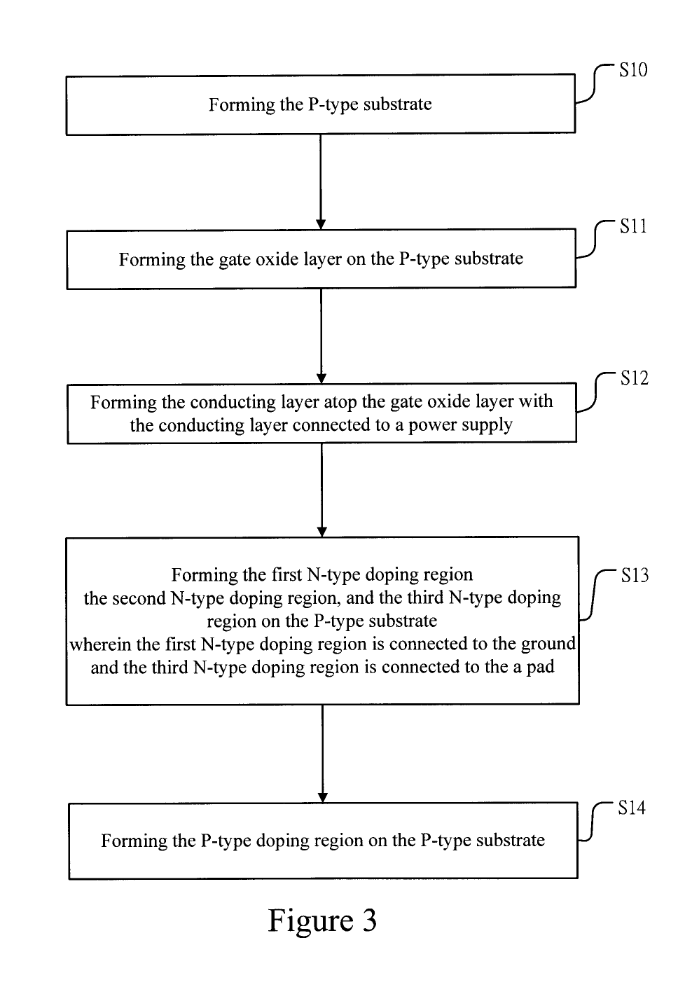

FIG. 3 shows a flowchart for manufacturing a MOSFET with the capability of voltage stabilizing and ESD protection, which is illustrated according to a preferred embodiment of the present invention. Referring to the flowchart, step S10 is executed to form the p-type substrate. Then, step S11 is executed to form the gate oxide layer, which is used as an insulating layer on the p-type substrate. In S12, the conducting layer is formed on the gate oxide layer connected to a power supply and is used as a gate electrode. Step S13 is executed to form the first n-type doping region, the second n-type doping region, and third n-type doping region on the p-type substrate, wherein the first n-type doping region is connected to the ground, and the third n-type doping region is connected to the pad. In step S13, ion implantation is used to form the first, the second, and the third n-type doping regions on the p-type substrate, where the first and the second n-type doping regions are formed on either side of the gate oxide layer. The first n-type doping region is used as a source electrode, and the third n-type doping region is used as a drain electrode which is connected to a power supply pad or an I/O pad. Step S14 is executed to form the p-type doping region on the p-type substrate, wherein the p-type doping region is used for grounding the p-type substrate.

When the chip is not installed on a circuit board or is not in operation, it is prone to the effects of static charges. The current generated by the static charges may pass through the pad and enter the third n-type doping region of the MOSFET when the energy of the static charges is greater than the potential barrier between the second and the third n-type doping regions. The second and the third n-type doping regions are thereby regarded as identical n-type doping regions. The current is then directed to ground via the PN junction formed between the n-type doping region and the p-type substrate, or via the NPN-bipolar-transistor effect generated by the n-type doping region, p-type substrate, and first n-type doping region. When the third n-type doping region is connected to the power supply pad, the current generated by the static charges will enter the MOSFET through the power supply pad and will then pass through the second n-type doping region via the third n-type doping region. Since the conducting layer is also connected to the power supply, the current can be directed to the first n-type doping region via the second n-type doping region and can then be directed to the ground.

On the other hand, during normal operation, a gate capacitor is formed by the conducting layer, the first n-type doping region, the second n-type doping region, and the p-type substrate, which is a voltage-stabilizing capacitor set between the power supply and ground.

In summary, a MOS device equipped with the capability of voltage stabilizing and ESD protection is presented, and chip space necessary for the additional voltage-stabilizing capacitors is thereby saved.

Accordingly, the present invention conforms to the legal requirements due to its novelty, non-obviousness, and utility. However, the foregoing description is only a preferred embodiment of the present invention, and is not used to limit the scope and range of the present invention. Those equivalent changes or modifications made according to the shape, structure, feature, or spirit described in the claims of the present invention are included in the appended claims of the present invention.

1. A metal-oxide-semiconductor (MOS) device, comprising:
a p-type substrate;
a gate oxide layer, located on the p-type substrate;
a first n-type doping region, located on the p-type substrate and on one side of the gate oxide layer and connected to a ground;
a second n-type doping region, located on the p-type substrate and on the other side of the gate oxide layer; and
a third n-type doping region, located on one side of the second n-type doping region and connected to a pad.

2. The MOS device of claim 1, wherein the pad is a power supply pad.

3. The MOS device of claim 1, wherein the pad is an input/output (I/O) pad.

4. The MOS device of claim 1, wherein a p-type doping region is formed on the p-type substrate and is connected to the ground.

5. The MOS device of claim 1, wherein the materials of the conducting layer include polysilicon.

6. The MOS device of claim 1, wherein n-type ions can be doped into the p-type substrate between the second n-type doping region and the third n-type doping region.

7. The MOS device of claim 6, wherein the concentration of the n-type ions can be adjusted according to different potential barriers.

8. The MOS device of claim 6, wherein p-type ions can be implanted into the p-type substrate between the second n-type doping region and the third n-type doping region.

9. The MOS device of claim 1, wherein the distance between the second n-type doping region and the third n-type doping region can be adjusted according to different potential barriers.

10. The MOS device of claim 1, wherein the conducting layer can be used as a gate electrode, the first n-type doping region can be used as a source electrode, and the third n-type doping region can be used as a drain electrode.

11. A method for manufacturing a metal-oxide-semiconductor (MOS) device, comprising the steps of:
forming a p-type substrate;
forming a gate oxide layer on the p-type substrate;
forming a conducting layer on the gate oxide layer with the conducting layer connected to a power supply; and
forming a first n-type doping region, a second n-type doping region, and a third n-type doping region on the p-type substrate, where the first n-type doping region is connected to a ground, and the third n-type doping region is connected to a pad.

12. The method for manufacturing the MOS device of claim 11, further comprising the step of forming a p-type doping region on the p-type substrate, the p-type doping region being connected to the ground.

13. The method for manufacturing the MOS device of claim 11, wherein the pad is a power supply pad.

14. The method for manufacturing the MOS device of claim 11, wherein the pad is an input/out (I/O) pad.

15. The method for manufacturing the MOS device of claim 11, wherein the method for manufacturing doping regions includes ion implantation.

16. The method for manufacturing the MOS device of claim 11, wherein n-type ions can be doped into the p-type substrate between the second n-type doping region and the third n-type doping region.

17. The method for manufacturing the MOS device of claim 16, wherein the concentration of the n-type ions can be adjusted according to different potential barriers.

18. The method for manufacturing the MOS device of claim 16, wherein p-type ions can be implanted into the p-type substrate between the second n-type doping region and the third n-type doping region.

19. The method for manufacturing the MOS device of claim 11, wherein the distance between the second n-type doping region and the third n-type doping region can be adjusted according to different potential barriers.
